(19) United States
(12) Patent Application Publication
(10) Pub. No.: US 2023/0056722 A1
(43) Pub. Date: Feb. 23, 2023

(54) POWER MODULE WITH IMPROVED ELECTRICAL AND THERMAL CHARACTERISTICS

(71) Applicant: Danfoss Silicon Power GmbH, Flensburg (DE)

(72) Inventors: Jörg BERGMANN, Nordborg (DK); Henning STRÖBEL-MAIER, Nordborg (DK)

(21) Appl. No.: 17/785,091

(22) PCT Filed: Dec. 18, 2020
(86) PCT No.: PCT/EP2020/086965

§ 371 Date: Jun. 14, 2022

(30) Foreign Application Priority Data
Dec. 28, 2019 (DK) PA201901556

(51) Int. Cl. H02M 7/00; H05K 1/18; H05K 1/02

(52) U.S. Cl. CPC H02M 7/003; H05K 1/181; H05K 1/0296; H05K 2201/10166

(57) ABSTRACT

A power module (1) includes a group of at least three rectangular electrical power components (11, 12, 13, 14, 23, 24, 25, 26) arranged on a substrate (2), wherein in that at least one side (31) of at least one of the rectangular electrical power components (11, 14) is not orthogonal or parallel to a line (3) that passes through the geometric centres of the remaining rectangular electrical power components (12, 13) of the group.

### CROSS-REFERENCE TO RELATED APPLICATION

This application is a National Stage application of International Patent Application No. PCT/EP2020/086965, filed on Dec. 18, 2020, which claims priority to Danish Application PA201901556, filed Dec. 28, 2019, each of which is hereby incorporated by reference in its entirety.

### TECHNICAL FIELD

This application related to power modules and, more specifically, to power modules with improved electrical and thermal characteristics.

### BACKGROUND

Semiconductor power modules are widely used in industry. For example, such a power module may be used for the controlled switching of high currents and can be used in power converters (such as inverters) to convert DC to AC or vice versa, or for converting between different voltages or frequencies of AC. Such inverters are used in motor controllers or interfaces between power generation or storage, or a power distribution grid. In addition, power modules are being increasingly utilised in vehicles, in particular electrical or hybrid vehicles, where the conversion or control of electrical power is important. In such an application, there are very great constraints on size, weight and efficiency.

A semiconductor power module is designed to fulfil two major characteristics: High power conversion efficiency and high power density. Factors such as lifetime, cost and quality are also taken into account. In order to achieve a high power density, high performance wide-bandgap semiconductors, such as Silicon Carbide (SiC) semiconductor switches may be used, as they generally outperform standard silicon based semiconductor switches, e.g. Insulated Gate Bipolar Transistors (IGBT). SiC devices put high demands on the design of the power module from thermal and electrical standpoint. The wide-bandgap semiconductors (e.g., SiC semiconductor switches) have the characteristic that they can switch very quickly, meaning that the transition from conduction to blocking mode takes only a few nanoseconds.

SiC MOSFETs are used as the semiconductor switches in applications where highest efficiency in a small volume is required by the application. SiC MOSFETs show fast switching speeds and low on-state resistance at the same time. Since SiC wafers are expensive to manufacture, and with current manufacturing processes it is hard to fabricate components with an acceptably low crystal failure amount, the die are typically very small (for example, 5-25 mm²). This keeps yield losses low, but restricts the total current that a SiC semiconductor switches can pass. In order to achieve high output powers, several of these small semiconductor switches (for example MOSFETs) need to be operated in parallel. In applications such as automotive power conversion, the use of multiple semiconductor switches in parallel takes up space within the semiconductor power module, yielding potentially larger modules. However, space is at a premium within a vehicle, and increasing the size of modules is not generally an option. It is therefore a great advantage if innovative design of layouts can both accommodate multiple semiconductor switches in parallel, a balanced (symmetric) operation, low stray inductance and small overall layout size.

Another aspect of good power module design is that there should be a very low thermal resistance (Rₜₕ ) path between a heat generating component, such as a semiconductor switch, and the means by which heat is removed from the module, such as a heat sink, a heat exchanger, or evaporator.

Low Rₜₕ is often obtained by siting the paralleled chips as far away from each other as possible.

Yet another aspect of good power module design is that there should be good current-sharing symmetry between paralleled semiconductor switches. This can be enabled by ensuring that the commutation loop of each semiconductor switch has a size equal to that of the other semiconductor switches which are connected in parallel. This yields a symmetric switching behaviour.

In the prior art power modules it is often the case that paralleled semiconductor switches are placed in a single row, and in close proximity to each other. This leads to a higher Rₜₕ due to thermal coupling between the semiconductor switches. To solve this problem, prior art power module designs often spread the semiconductor switches out, so they are positioned at a distance from each other, to reduce the thermal resistance path. However, this often leads to a degraded switching symmetry, such as significant differences in the size of the commutation loops, and so to electrically worse solutions.

### SUMMARY

The current invention leads to a power module layout which successfully equalises commutation loops between paralleled semiconductor switches.

Additionally, the current invention enables a power module layout where the paralleled semiconductor switches are divided into two groups which are (ideally) arranged axis-symmetrically. This enables the minimization of the electrical distance between the chips of one group, but leaves the real distance as large as possible. This significantly reduces the thermal resistance of the heat-conducting path.

It is, thus, an object of the present invention to provide a power module which is capable of exhibiting the simultaneous switching and balanced operation of multiple semiconductor switches in parallel, lower stray inductances, and more stable and efficient operation than currently available power modules.

It is a further object of the present invention to provide a semiconductor power module with a reduced thermal resistance in comparison to similar prior art modules.

According to a first aspect of the present invention the above and other objects are fulfilled by providing a power module comprising a group of at least three rectangular electrical power components arranged on a substrate, wherein in that at least one side of at least one of the rectangular electrical power components is not orthogonal or parallel to a line that passes through the geometric centres of the remaining rectangular electrical power components of the group.

The substrate may comprise an insulating base, with conducting tracks to form the circuitry required, attached to the insulating base. A suitable substrate may be a DBC (direct bonded copper) substrate formed of two conducting copper layers either side of an insulating ceramic layer. Other suitable substrates may include DBA (direct bonded aluminium) or other substrates well known in the field.

In one embodiment, the geometric centres of all of the rectangular electrical power components that comprise the group are disposed along a straight line.

In another embodiment, the group of rectangular electrical power components are electrically connected in parallel.

In a further embodiment, the rectangular electrical power components are semiconductor switches. The term “semiconductor switches” is here used to include any of a number of known semiconductor switching devices. Examples of such devices are Thyristors, JFETs, IGBTs and MOSFETs, and they may be based on traditional silicon technology or wide band-gap technologies such as silicon carbide (SiC). Gallium nitride (GaN) devices may also suitable.

The power module may provide the functionality of a half bridge circuit.

In a preferred embodiment of the invention, the substrate may comprise an inner load track, two intermediate load tracks and two outer load tracks, each of which load tracks is elongated and extends substantially across the substrate in a first direction, and wherein the two intermediate load tracks are arranged adjacent to the inner load track, and each outer load track is arranged on the opposite side of one of the two intermediate load tracks with respect to a second direction which is substantially orthogonal to the first direction, and wherein the power module comprises two first sets of semiconductor switches, each first set of semiconductor switches being mounted on the inner load track and electrically connected to the an intermediate load track, such that the first sets of semiconductor switches form a first arm of the half bridge circuit, and wherein the power module comprises two second sets of semiconductor switches, each second set of semiconductor switches being mounted on an intermediate load track and electrically connected to an outer load track, such that the second sets of semiconductor switches form a second arm of the half bridge circuit.

The term “track” is here used to specify a circuit track formed from a metal layer forming part of the substrate and insulated from other tracks by a gap. The term “load track” is here used to specify a track suitable for carrying a large current, such as that supplying the electrical load for which the power module is supplying power. Suitability for large currents may be a combination of the width of the track and thickness of the track, forming a large cross-sectional area and thus allowing the passage of large currents without undue heating.

The term “mounted” is here used to mean the permanent connection of a device to a track, and may include an electrically conducting connection. Means of such connections include soldering, brazing and sintering.

The term “electrically connected to” is here used to mean the connection of part of the device to a remote track or other device. Traditionally this form of connections made using metallic wirebonds comprising aluminium. However, other metals such as copper may be usable. The term also covers the use of ribbon or tape bonds, braided tapes and the use of solid metal structures such as clips or busbars.

The external DC power terminals may be arranged at one end of the module in the first direction, and one or more AC power terminals may be arranged at the opposite end of the module in the first direction.

In yet another preferred embodiment of the inventive power module, the angle between a side of at least one of the rectangular electronic power components and a line that passes through the geometric centres of the remaining rectangular electrical power components of the group is within the range 30°-60°, preferably between 40° and 50°, and even more preferably 45°

### BRIEF DESCRIPTION OF THE DRAWINGS

The invention will become more fully understood from the detailed description given herein below. The accompanying drawings are given by way of illustration only, and thus, they are not limitative of the present invention. In the accompanying drawings:

FIG. 1 shows a plan view of a substrate layout forming part of a first embodiment of the invention;

FIG. 2 illustrates the relationship between the distribution of semiconductor switches and the line which runs through the geometric centres of semiconductor switches;

FIG. 3 shows a cross section through an embodiment of the current invention;

FIG. 4 shows a prior art layout of wirebonds and semiconductor switches;

FIG. 5 shows a modified version of the layout shown in FIG. 4;

FIG. 6 shows a second embodiment of the current invention;

FIG. 7 shows the track layout and semiconductor switch placement of a third embodiment of the current invention;

FIG. 8 shows a fourth embodiment of the current invention;

FIG. 9 shows a fifth embodiment of the current invention;

FIG. 10 shows another representation of the fifth embodiment of the current invention showing the DC and AC terminals, together with control terminals;

FIG. 11 shows a perspective view of the fifth embodiment of the current invention, and

FIG. 12 shows a representation of the pad area on the upper surface of a semiconductor switch together with the area required for bonding a wirebond.

### DETAILED DESCRIPTION

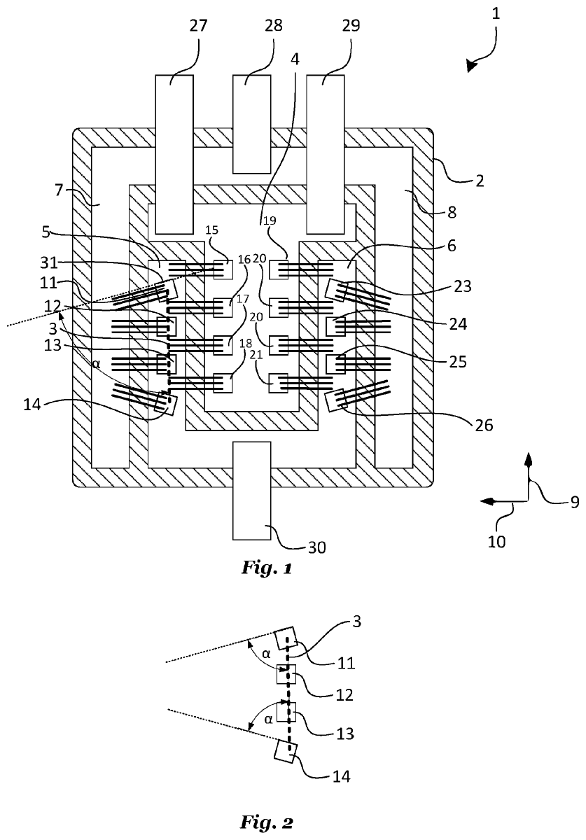

Referring now in detail to the drawings for the purpose of illustrating preferred embodiments of the present invention, a first embodiment of the inventive module comprises the substrate, layout of tracks and distribution of semiconductors shown in FIG. 1.

Here, the substrate 2 comprises an inner load track 4, two intermediate load tracks 5, 6 and two outer load tracks 7, 8, each of which load tracks is elongated and extends substantially across the substrate 2 in a first direction 9. The two intermediate load tracks 5, 6 are arranged adjacent to the inner load track 4, and each outer load track 7, 8 is arranged on the opposite side of one of the two intermediate load tracks 5, 6 to that of the inner load track 4 with respect to a second direction 10, which is substantially orthogonal to the first direction 9. Also shown are two first sets of semiconductor switches 15-18, 19-22, each first set of semiconductor switches being mounted on the inner load track 4 and electrically connected to an intermediate load track 5, 6, such that the first sets of semiconductor switches form a first arm of a half bridge circuit. The module also comprises two second sets of semiconductor switches 11-14, 23-26, each second set of semiconductor switches being mounted on an intermediate load track 5, 6 and electrically connected to an outer load track 7, 8, such that the second sets of semiconductor switches form a second arm of the half bridge circuit.

The two second sets of semiconductor switches 11-14, 23-26, are shown distributed into two groups in such a way that the semiconductor switches 11, 14, 23, 26, which lie at the ends of the linear distribution of semiconductor switches, are rotated with respect to the other semiconductor switches in the linear distribution so that their sides are at a non-orthogonal and non-parallel angle a to a line 3 that passes through the geometric centres of the remaining semiconductor switches 12, 13, 24, 25 of the group.

FIG. 2 illustrates the relationship between the distribution of semiconductor switches 11, 12, 13, 14 and the line 3, which runs through the geometric centres of semiconductor switches 12 and 13. Here the angle a between the sides of the outer semiconductor switches 11, 14 and the line 3 is shown.

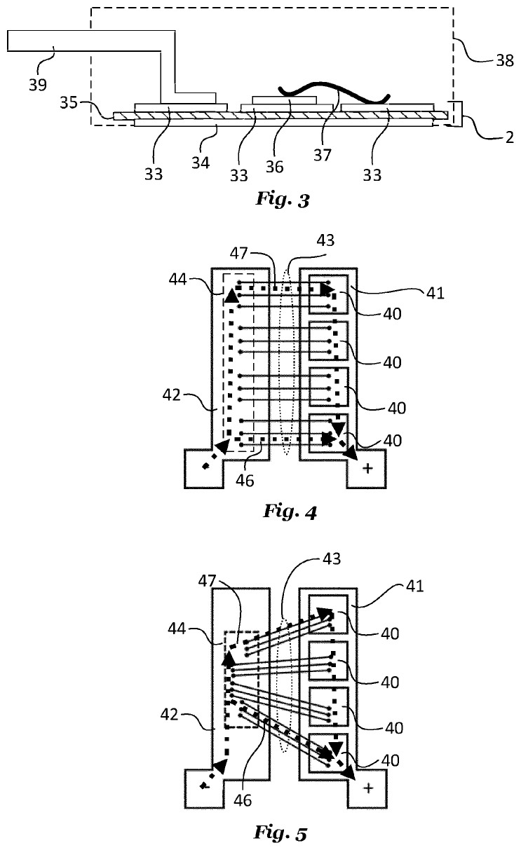

FIG. 3 shows a cross section through an embodiment of the current invention showing in more detail the structure on the substrate 2. Here, the substrate 2 is a direct bonded copper (DBC) substrate comprising a lower copper layer 34, a ceramic core 35 and an upper copper layer 33. The upper copper layer 33 has been formed as individual conducting tracks which form the circuitry connecting components which form the electronics of the semiconductor power module. Connections between a semiconductor switch 36 and an adjacent track are made here by a wirebond 37. Also shown is a lead frame 39 which connects one of the tracks to the outside of the module. Such a lead frame connection may be used for power and/or control connections in and out of the power module. In this embodiment the power module is encased in a mould compound 38 which protects the circuitry and components within the module from humidity, dust or physical damage.

One characteristic of the of the first embodiment shown in FIG. 1 is that the terminations of the wirebonds which connect the semiconductor switches 11, 12, 13, 14 and 23, 24, 25, 26 to the outer load tracks 7, 8 are closer together than the opposite terminations of the wirebonds where they are connected to the semiconductor switches 11, 12, 13, 14 and 23, 24, 25, 26.

FIG. 4 shows a prior art layout wherein a set of semiconductor switches 40 are mounted on a positive load track 41 and are electrically connected to a negative load track 42 via a set of wire bonds 43. The landing area 44 of the wirebonds 43 has a similar extent to that of the opposite ends of wirebonds, which that of the semiconductor switches 40 themselves.

In FIG. 5 is shown a modified layout of FIG. 4 where a set of semiconductor switches 40 are mounted on a positive load track 41 and are electrically connected to a negative load track 42 via a set of wirebonds 43. Here, however, the landing area 45 of the wirebonds 43 a substantially smaller than the extent of the semiconductor switches 40 themselves. This feature is also present in the first embodiment of the current invention shown in FIG. 1. The distribution of the wirebonds in this way improves performance, since the difference between the length of the commutation loops through the semiconductor switches in the extreme positions is greatly reduced. This can be seen by the arrows describing the shortest 46 and longest 47 commutation loops shown in FIG. 4 (where there is a significant difference between the two commutation loop path lengths) and FIG. 5 (where the difference is greatly reduced).

It is very difficult to reliably place wirebonds at an angle shown in FIG. 5, particularly for the outer semiconductor switches, since there is a limit the angle that a wirebond may have to the pad on a semiconductor switch. This is illustrated in FIG. 12 where 48 shows the pad area on the upper surface of a semiconductor switch 59 and 49 the area required for bonding a wirebond. The angle (3 is the maximum deviation of the axis 60 of the wirebond to the axis 61 of the pad 48 for the reliable bonding of the wirebond. It is therefore an advantage to rotate the semiconductor switches themselves if wirebonds need to the placed at an angle as a shown in the first embodiment and in FIG. 5.

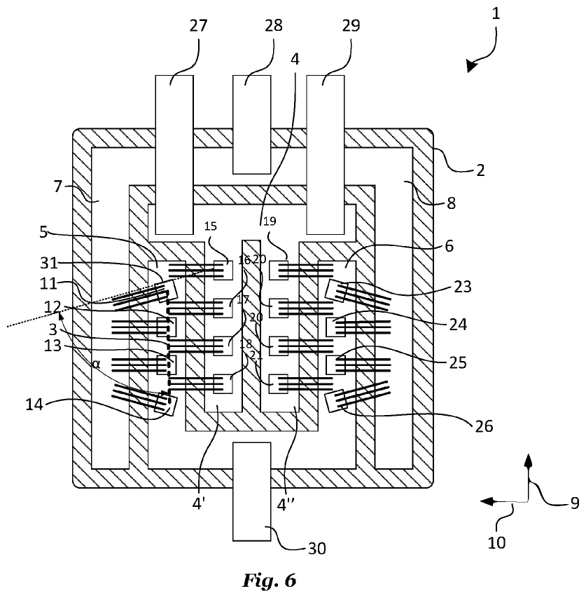

FIG. 6 shows a second embodiment of the invention, where the layout shown in FIG. 1 is slightly modified by the introduction of a split in the inner load track 4 into two arms, 4′, 4″. Such a split between the two arms of the inner load track allows the placing of a gate track in close proximity to all of the inner semiconductor switches 15, 16, 17, 18, 19, 20, 21, 22.

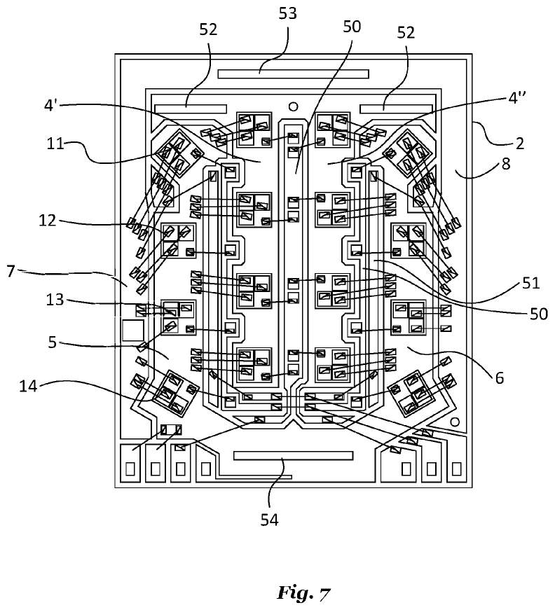

FIG. 7 illustrates the track layout and semiconductor switch placement of a third embodiment of the invention. In essence, this embodiment is similar to that shown in the second embodiment (FIG. 6) but shows, in addition, the presence of gate tracks 50 and sense tracks 51, positioned between the intermediate load tracks 5, 6 and the inner load track 4′, 4″, and also between the two arms of the inner load track 4′, 4″. Landing pads for connection of external terminals are also shown here. Those for the positive terminal 52 are placed on the inner load track 4, and a single landing pad for positive terminal 53 is placed on the track connecting the two outer load tracks 7, 8. A landing pad for the AC terminal is shown on the track connecting the two intermediate load tracks 5,6.

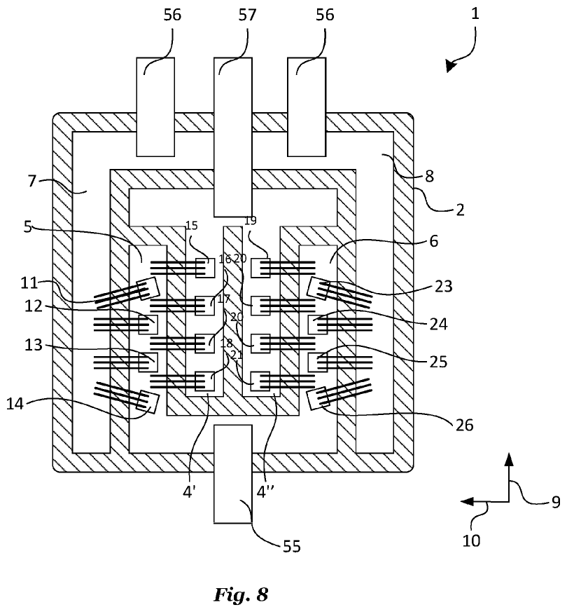

FIG. 8 illustrates a fourth embodiment of the invention. Here the polarity of the DC connectors is reversed, but the layout of the mounted tracks and of the semiconductor switches is largely unchanged from the layout shown in FIG. 6. In FIG. 8 the AC terminal 55 is at one end of the substrate 2, and the positive 57 and negative 56 terminals are at the opposite end.

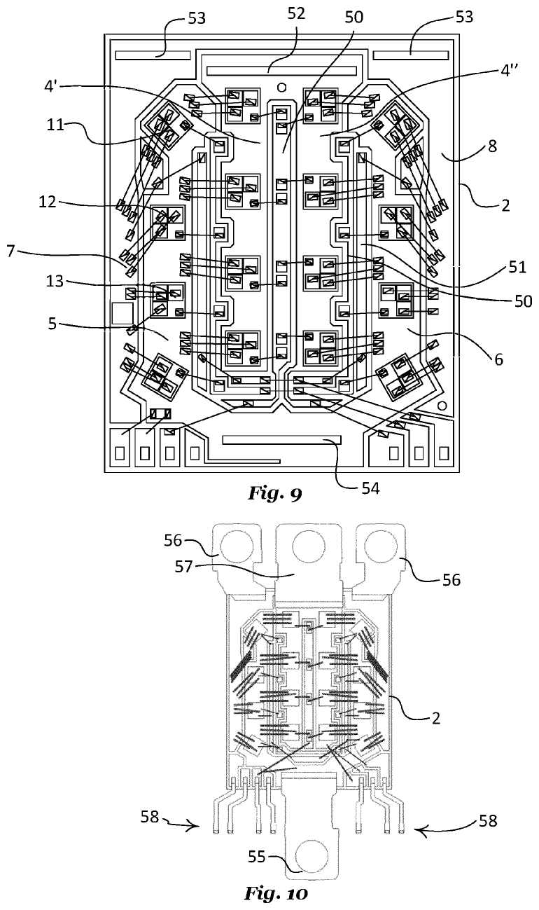

FIG. 9 shows a fifth embodiment of the invention, here illustrating the placement of gate tracks 50 and sense tracks 51.

FIG. 10 is a representation of the fifth embodiment, based on that shown in FIG. 8, here showing the DC 56, 57 and AC terminal 55, together with control terminals 58.

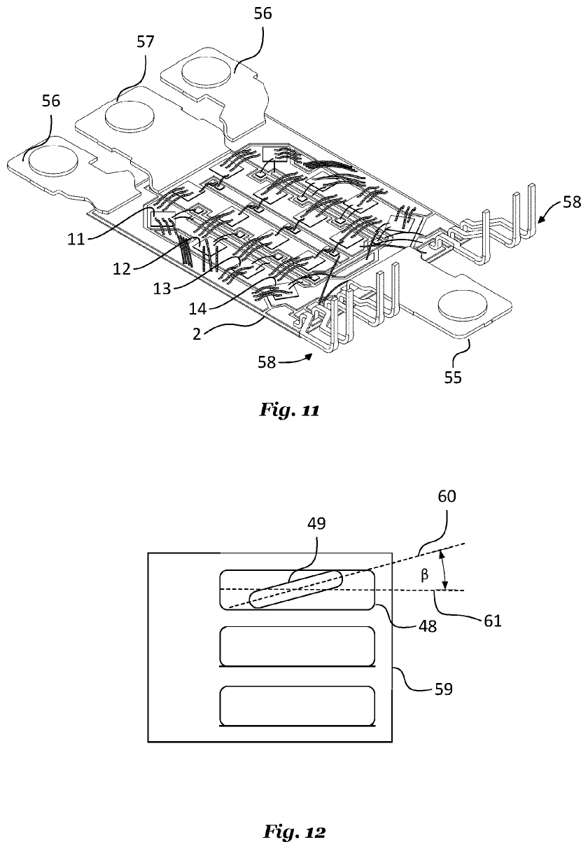

FIG. 11 shows a perspective view of the fifth embodiment with the substrate 2, semiconductor switches 11-14, load terminals 56, 57, 55 and control terminals 58 attached.

While the present disclosure has been illustrated and described with respect to a particular embodiment thereof, it should be appreciated by those of ordinary skill in the art that various modifications to this disclosure may be made without departing from the spirit and scope of the present disclosure.

1. A power module comprising a group of at least three rectangular electrical power components arranged on a substrate, wherein in that at least one side of at least one of the rectangular electrical power components is not orthogonal or parallel to a line that passes through the geometric centres of the remaining rectangular electrical power components of the group.

2. The power module according to claim 1, wherein the geometric centres of all of the rectangular electrical power components that comprise the group are disposed along a straight line.

3. The power module according to claim 1, wherein the group of rectangular electrical power components are electrically connected in parallel.

4. The power module according to claim 1, wherein the rectangular electrical power components are semiconductor switches.

5. The power module according to claim 4, wherein the power module provides a half bridge circuit.

6. The power module according to claim 5, wherein the substrate further comprises an inner load track, two intermediate load tracks and two outer load tracks, each of which load tracks is elongated and extends substantially across the substrate in a first direction;
wherein the two intermediate load tracks are arranged adjacent to the inner load track, and each outer load track is arranged on the opposite side of one of the two intermediate load tracks to that of the inner load track with respect to a second direction substantially orthogonal to the first direction;
wherein the power module comprises two first sets of semiconductor switches, each first set of semiconductor switches being mounted on the inner load track and electrically connected to an intermediate load track, such that the first sets of semiconductor switches form a first arm of the half bridge circuit;
wherein the power module comprises two second sets of semiconductor switches, each second set of semiconductor switches being mounted on an intermediate load track and electrically connected to an outer load track, such that the second sets of semiconductor switches form a second arm of the half bridge circuit.

7. The power module according to claim 4, wherein the external DC power terminals are arranged at one end of the module in the first direction, and one or more AC power terminals are arranged at the opposite end of the module in the first direction.

8. The power module according to claim 1, wherein the angle between a side of at least one of the rectangular electronic power components and a line that passes through the geometric centres of the remaining rectangular electrical power components of the group is within the range 30-60°.

9. The power module according to claim 1, wherein the angle between a side of at least one of the rectangular electronic power components and a line that passes through the geometric centres of the remaining rectangular electrical power components of the group is 45°.
